(19) United States
(12) Patent Application Publication
(10) Pub. No.: US 2022/0007515 A1
(43) Pub. Date: Jan. 6, 2022

(54) FLEXIBLE PRINTED ARTICLES

(71) Applicant: Hewlett-Packard Development Company, L.P., Spring, TX (US)

(72) Inventors: Robert C. Ionescu, Palo Alto, CA (US); Helen A. Holder, Palo Alto, CA (US); Jarrid A. Wittkopf, Palo Alto, CA (US); Robyn Worsley, Manchester (GB); Cinzia Casiraghi, Manchester (GB); James P. Shields, Corvallis, OR (US)

(73) Assignee: Hewlett-Packard Development Company, L.P., Spring, TX (US)

(21) Appl. No.: 17/298,641

(22) PCT Filed: Aug. 29, 2019
(86) PCT No.: PCT/US2019/048841

§ 371 Date: May 31, 2021

(51) Int. Cl. H05K 3/12; B29C 64/124; H05K 1/09; H05K 1/03; H05K 1/18; G06F 1/16; G01L 1/22; B33Y 70/10; B33Y 80/00; C09D 11/52; C09D 11/037; C01B 32/198

(52) U.S. Cl. CPC H05K 3/125; B29C 64/124; H05K 1/092; H05K 1/0393; H05K 1/0326; H05K 1/189; B33Y 10/00; G01L 1/2287; B33Y 70/10; B33Y 80/00; C09D 11/52; C09D 11/037; C01B 32/198; G06F 1/163

(57) ABSTRACT

One example of a flexible printed article includes a non-conductive, graphene oxide membrane base substrate; and an electronic component positioned on the non-conductive, graphene oxide membrane base substrate. An example method for generating this example of the flexible printed article includes inkjet printing a conductive ink directly on the non-conductive graphene oxide membrane base substrate.

### BACKGROUND

Computing devices are embedded in everyday objects, from smaller portable objects, such as wearable devices (e.g., watches, activity trackers, etc.) and headphones, to larger objects, such as lamps, coffee makers, refrigerators, etc. The interconnection of these computing devices (i.e., the Internet of things, IoT) enables them to send and receive data. Portable objects, in particular, may experience lots of wear and tear. Thus, it is desirable for the computing devices in these objects to be reliable and resilient.

### BRIEF DESCRIPTION OF THE DRAWINGS

Features of examples of the present disclosure will become apparent by reference to the following detailed description and drawings, in which like reference numerals correspond to similar, though perhaps not identical, components. For the sake of brevity, reference numerals or features having a previously described function may or may not be described in connection with other drawings in which they appear.

FIG. 1 is a schematic, perspective view of an example of a flexible printed article;

FIG. 2 is a schematic flow diagram illustrating an example of a three-dimensional (3D) printing method;

FIG. 3 is a graph depicting the sheet resistance (R_{S} (kΩ/sq), Y-axis) of a printed graphene line on an example base substrate (a graphene oxide membrane, GOM) and two comparative base substrates (white office paper and a paper designed for inkjet printing) versus the number of printing passes (X-axis) used to generate the printed line;

FIGS. 4A and 4B are schematic illustrations of a bending test performed on example printed articles and comparative example printed articles, where FIG. 4A illustrates the flat position of the sample and FIG. 4B illustrates the bent (curved) position of the sample;

FIG. 5 is a graph depicting the average normalized resistance (R/R₀, Y-axis) versus the number of bending cycles (X-axis) for three example printed articles and three comparative example printed articles exposed to the bending test shown in FIGS. 5A and 5B, where resistance measurements were taken when the articles were in the flat position and in the bent (curved) position;

FIG. 6A is a graph depicting the resistance (Ω, Y-axis) of an example strain sensor attached to a box versus time (seconds (s), X-axis) as the box was opened and closed; and

FIG. 6B is a graph depicting the resistance (Ω, Y-axis) of a comparative example strain sensor printed on a box versus time (seconds (s), X-axis) as the box was opened and closed.

### DETAILED DESCRIPTION

Printed flexible articles are disclosed herein. In some instances, the printed flexible article is generated using an inkjet printing technique, such as thermal or piezoelectric inkjet printing. The printed flexible article may also be generated using a three-dimensional printing process.

The printed flexible article includes a non-conductive, graphene oxide membrane base substrate and an electronic component positioned on the non-conductive, graphene oxide membrane base substrate. In some of the examples disclosed herein, the graphene oxide membrane serves as the base substrate, and thus it is not sandwiched between or positioned on other substrate materials.

In some examples, the graphene oxide membrane is the base substrate upon which a water-based ink is directly applied. The graphene oxide membrane exhibits high permeability to water (>10⁻⁷ mm·g/cm²·s·bar), which is particularly suitable for absorbing the vehicle of the water-based ink and allowing conductive particles, pigment, or other solids of the water-based ink to remain at or near the surface of the graphene oxide membrane. The graphene oxide membrane also has smoother surface (e.g., surface roughness is about 1 μm RMS) than commercial paper substrates (e.g., surface roughness is >3 μm RMS). This can improve the image quality of a printed image and/or the conductivity of a printed electronic component.

Moreover, it has been found that both the graphene oxide membrane and the ink printed thereon exhibit enhanced resilience when exposed to repetitive bending and when compared to treated or untreated paper substrates.

Throughout this disclosure, a weight percentage that is referred to as “wt % active” refers to the loading of an active component of a dispersion or other formulation that is present in the conductive (or semi-conductive or insulating) ink and/or fusing agent. For example, conductive nanoparticles, such as silver nanoparticles, may be present in a water-based formulation (e.g., a stock solution or dispersion) before being incorporated into the conductive ink. In this example, the wt % actives of the silver nanoparticles accounts for the loading (as a weight percent) of the silver nanoparticle solids that are present in the conductive ink, and does not account for the weight of the other components (e.g., water, co-solvent(s), etc.) that are present in the stock solution or dispersion with the silver nanoparticles. The term “wt %,” without the term actives, refers to either i) the loading (in the ink or the fusing agent) of a 100% active component that does not include other non-active components therein, or ii) the loading (in the ink or the fusing agent) of a material or component that is used “as is” and thus the wt % accounts for both active and non-active components.

Flexible Printed Article

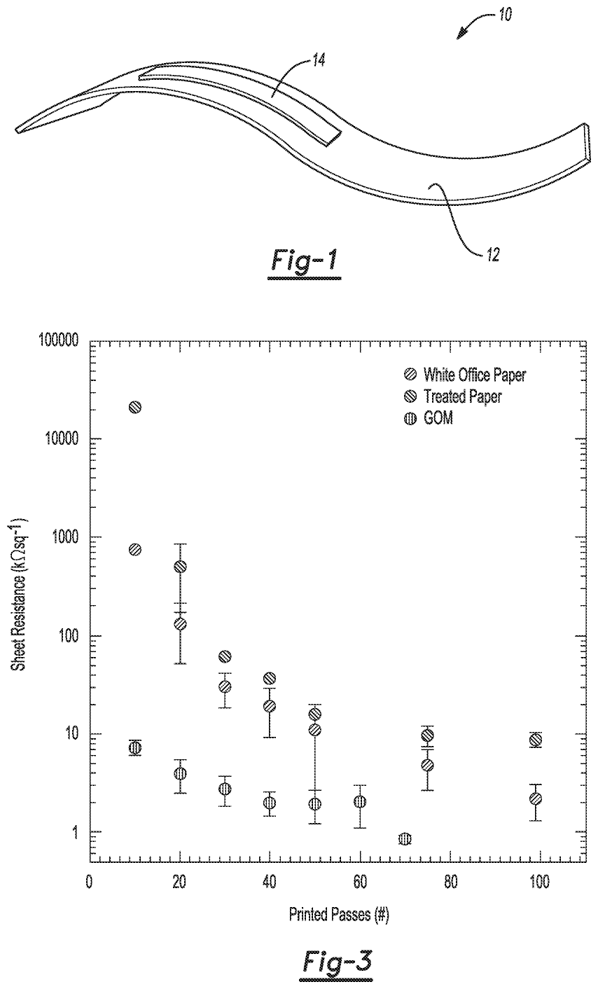

An example of the flexible printed article 10 is schematically shown in FIG. 1. The flexible printed article 10 includes a non-conductive, graphene oxide membrane base substrate 12; and an electronic component 14 positioned on the non-conductive, graphene oxide membrane base substrate. In the example shown in FIG. 1, a single electronic component 14 is shown, however, it is to be understood that a plurality of electronic components 14 may be positioned on the non-conductive, graphene oxide membrane base substrate 12.

The flexible printed article 10, and in particular, some examples of the electronic component 14, have been found to be extremely durable and resilient. In particular, electronic components 14 that have been printed with a graphene nanosheet ink exhibit excellent durability and resilience. The durability and resilience may be tested by bending the flexible printed article 10 and measuring the resistance of the electronic component 14. Examples of the printed conductive ink (on the graphene oxide membrane) disclosed herein have exhibited a normalized resistance that remains within 10% of an initial normalized resistance over 30,000 bending cycles.

Non-Conductive, Graphene Oxide Membrane Base Substrate

The non-conductive, graphene oxide membrane base substrate 12 is a thin film (a graphene oxide membrane) consisting of several graphene oxide nanosheets. In the graphene oxide membrane, the individual graphene oxide nanosheets may be interlocked/tiled together in a near-parallel or parallel arrangement to form a free-standing membrane. In some of the examples disclosed herein, the non-conductive, graphene oxide membrane base substrate 12 consists of the graphene oxide membrane, and thus the graphene oxide membrane is not positioned on another substrate and are not doped with fillers, additives, etc.

Graphene oxide may be formed by oxidizing graphite, which introduces oxygen-containing groups (e.g., hydroxyl groups (—OH), carboxyl groups (—COOH), carbonyl groups

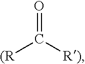

and/or epoxide groups

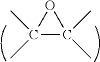

to the graphite structure. It is to be understood that graphene oxide is a disordered material, and the exact structure and chemical composition may vary, depending, in part, upon how it is produced. In one example, the composition of the graphene oxide includes from about 49% to about 56% of carbon, from about 0% to about 1% of hydrogen, from about 0% to about 1% of nitrogen, from about 0% to about 2% of sulfur, and from about 41% to about 50% of oxygen.

In an example, graphene oxide may be formed by sonication in water of oxidized graphite. In an example, graphite is oxidized by a strong oxidizing agent in a concentrated acid. An example of this method is the Hummers method, in which graphite is oxidized by a solution of potassium permanganate in sulfuric acid. Graphene oxide membranes may be formed using graphene oxide in a flow-directed assembly method. In this method, colloidal dispersions of individual graphene oxide nanosheets are prepared in water using sonication. Filtration of the dispersion leaves the colloid on the filter, which can then be dried and peeled from the filter to form the membrane. Graphene oxide and graphene oxide membranes are also commercially available.

The graphene oxide membrane is non-conductive (due, in part, to the disrupted sp2 bonding networks), and thus is electrically insulating. The electrically insulating property of the graphene oxide membrane is desirable so that it does not interfere with the electrical conductivity of the electrical component 14 formed thereon.

The thickness of the graphene oxide membrane may range from about 1 μm to about 100 μm. In an example, the thickness may range about 5 μm to about 75 μm. In another example, the thickness is about 20 μm. Increased thicknesses may deleteriously affect the flexibility of the non-conductive base substrate 12, and thus of the flexible printed article 10. Decreased thicknesses will make the membrane 12 difficult to manipulate and use.

Electronic Component

The electronic component 14 may be any printable electronic device, including conductive components printed using conductive inks, semi-conductive components printed using semi-conductive inks, or insulating components printed using insulating inks. As examples, the electronic component 14 may be a conductive trace or track, a conductive contact pad, transistors, diodes, capacitors, memristors, energy storage devices (e.g., supercap, batteries, etc.), radio-frequency identification devices (RFID), light-emitting devices, sensors (e.g., strain, chemical, photo, etc.), etc.

In some examples, the electronic component 14 is formed on the non-conductive, graphene oxide membrane base substrate 12 with an ink including a conductive material, a semi-conductive material, or an insulating material. In some examples, the electronic component 14 includes the solids of a water-based conductive ink that is printed on the non-conductive, graphene oxide membrane base substrate 12. In other examples, the electronic component 14 includes the solids of a water-based semi-conductive ink that is printed on the non-conductive, graphene oxide membrane base substrate 12. In still other examples, the electronic component 14 includes the solids of a water-based insulating ink that is printed on the non-conductive, graphene oxide membrane base substrate 12. The graphene oxide membrane enables rapid absorption of the water-based vehicle of the ink, leaving the solids (including the functional conductive, semi-conductive, or insulating material) at the surface of the substrate 12.

In some examples, the conductive ink is a water-based ink, and the solids include conductive nanomaterials (or some other conductive material). In other examples, the semi-conductive ink is a water-based ink, and the solids include semi-conductive nanomaterials (or some other semi-conductive material). In still other examples, the insulating ink is a water-based ink, and the solids include insulating nanomaterials (or some other insulating material). In any these examples, the ink may include (or consist of) the conductive, semi-conductive, or insulating material and water. In another of these examples, the ink may include, in addition to the conductive/semi-conductive/insulating material and the water, co-solvent(s), dispersant(s), surfactant(s), a pH adjuster, an anti-kogation agent(s), biocide(s), surface tension modifiers, and/or viscosity modifiers.

Any conductive material may be used that, when applied on the non-conductive, graphene oxide membrane base substrate 12 and dried, forms an element that is capable of conducting electricity. In some examples, the conductive material may also act as a colorant in the conductive ink.

The conductive material may be any material that is capable of conducting electric current. In one example, the conductive material is silver (Ag), copper (Cu), gold (Au), platinum (Pt), nickel (Ni), palladium (Pd), iron (Fe), chromium (Cr), aluminum (Al), or zinc (Zn). Other examples of suitable conductive materials include metal alloys (where the metals are selected from, for example, Ag, Au, Cu, Fe, Sn, Ti, Mn Ni, Rh, Ru, Mo, Ta, Ti, Pt, or Pd), metal oxide (e.g., iron oxide), metal coated oxide (e.g., iron oxide coated with Ag, Au or Pt), cadmium selenide, or metal coated silica (e.g., silica coated with Ag or Au). Still other examples of suitable conductive materials include carbon black or other carbon analogs (e.g., carbon nanotubes, graphene, etc.). It is to be understood that any combinations of the previously listed conductive materials may also be used.

The conductive material may have a morphology that is inkjettable, including nanomaterials, such as nanoparticles, nanotubes, nanorods, nanowires, etc. The largest dimension of any of these example morphologies may be on the nano-scale (e.g., from about 1 nm to about 1000 nm). In an example, the average particle size (e.g., volume or number weighted mean diameter), diameter, or other dimension of the conductive materials may range from about 1 nm to about 500 nm. As other examples, the average particle size, diameter, or other dimension of the conductive materials may range from about 50 nm to about 500 nm, or from about 1 nm to about 200 nm, or from about 200 nm to about 300 nm, etc.

The conductive material may be any conductive nanomaterial, such as conductive nanoparticles, nanorods, nanowires, nanotubes, nanosheets, etc. In one example, the conductive material includes conductive nanomaterials that are selected from the group consisting of graphene nanomaterials, carbon nanomaterials, metal nanomaterials, metallic transition metal chalcogenide nanomaterials, conductive polymer nanomaterials, and combinations thereof. Example graphene materials include graphene nanosheets. Example carbon materials include carbon nanoparticles and/or carbon nanotubes (e.g., multi-walled carbon nanotubes, conductive single-walled carbon nanotubes, etc.). Example metal materials include metallic nanoribbons, silver nanoparticles, copper nanoparticles, gold nanoparticles, platinum nanoparticles, nickel nanoparticles, palladium nanoparticles, iron nanoparticles, chromium nanoparticles, and/or aluminum nanoparticles. Example metallic transition metal chalcogenides may be represented by MX₂, where M is a transition metal atom and X is a chalogen atom (e.g., MoS₂, ReS₂, WS₂, WSe₂, MoSe₂, etc.). Examples of conductive polymers include poly(3,4-ethylenedioxythiophene) polystyrene sulfonate (PDOT:PSS) and poly(3,4-ethylenedioxythiophene) polytrimethylene terephthalate (PDOT:PTT). Still other examples of suitable conductive materials may be represented by (NH₄)₂MX₄, such as (NH₄)₂MoS₄, (NH₄)₂WS₄ etc. and M-xenes.

The conductive material may be present in the conductive ink in an amount that allows the conductive ink to efficiently introduce the conductive material to the non-conductive, graphene oxide membrane base substrate 12. The conductive material may also be present in the conductive ink in an amount that allows the conductive ink to jettable via thermal or piezoelectric printing. In some examples, the conductive material may be present in the conductive ink in an amount ranging from about 0.1 wt % active to about 65 wt % active, based on a total weight of the conductive ink. In other examples, the conductive material may be present in the conductive ink in an amount ranging from about 0.2 wt % active to about 5 wt % active, from about 1 wt % active to about 50 wt % active, from about 15 wt % active to about 45 wt % active, or from about 0.5 wt % active to about 55 wt % active, based on a total weight of the conductive ink. Higher conductive material concentrations may provide better conductivity due to a larger amount of conductive material being deposited on the non-conductive base substrate 12. When lower conductive material concentrations are used, more of the conductive ink may be applied to achieve the desired amount of conductive material, and therefore the desired amount of conductivity, in the conductive element 14.

Any semi-conductive material may be used that, when applied on the non-conductive, graphene oxide membrane base substrate 12 and dried, forms an element that is electrically semi-conducting. Example semi-conductive materials may include semi-conducting metal oxides, graphene nanoribbons, or a combination of quantum dots and semi-conducting polymers. In some examples, the semi-conductive material may be present in the semi-conductive ink in an amount ranging from about 0.1 wt % active to about 65 wt % active, based on a total weight of the semi-conductive ink.

Any insulating material may be used that, when applied on the non-conductive, graphene oxide membrane base substrate 12 and dried, forms an element that through which very little or no electric current will flow. Example insulating materials may include insulating nanomaterials (nanoparticles, nanorods, nanowires, nanotubes, nanosheets, etc.), carbon buckyballs, colloids, silicon sol-gel precursors (silicates), insulating polymers (e.g., polylactic acid, fluoropolymers, polycarbonate, acrylics, polystyrene, SU-8, ete.), some metal oxide nanomaterials (e.g., barium titanate, titanium dioxide, zinc oxide,), and insulating small molecules (i.e., having a molecular mass less than 5,000 Daltons, e.g., benzocyclobutane, paraffins, organic dyes, etc.). In some examples, the insulating material may be present in the insulating ink in an amount ranging from about 0.1 wt % active to about 65 wt % active, based on a total weight of the insulating ink.

The term “water-based ink” means a liquid which contains water, e.g. which contains greater than 20% by volume water. The water-based ink may also include other components, e.g., in addition to the conductive, semi-conductive, or insulating material. As mentioned, some examples of the ink may further include co-solvent(s), surfactant(s), a pH adjuster, an anti-kogation agent(s), and/or antimicrobial agent(s). Still other examples of the conductive ink may further include co-solvent(s), humectant(s), dispersant(s), surfactant(s), antimicrobial agent(s), anti-kogation agent(s), chelating agent(s), buffer(s), viscosity modifiers, and/or surface tension modifiers.

Classes of organic co-solvents that may be used in the ink include aliphatic alcohols, aromatic alcohols, diols, glycol ethers, polyglycol ethers, lactams, formamides, acetamides, glycols, and long chain alcohols. Examples of these co-solvents include primary aliphatic alcohols, secondary aliphatic alcohols, 1,2-alcohols, 1,3-alcohols, 1,5-alcohols, 1,6-hexanediol or other diols (e.g., 1,5-pentanediol, 2-methyl-1,3-propanediol, etc.), ethylene glycol alkyl ethers, propylene glycol alkyl ethers, higher homologs (C₆-C₁₂) of polyethylene glycol alkyl ethers, triethylene glycol, tetraethylene glycol, tripropylene glycol methyl ether, N-alkyl caprolactams, unsubstituted caprolactams, 2-pyrrolidone, N-methylpyrrolidone, 1-methyl-2-pyrrolidone, 1-(2-hydroxyethyl)-2-pyrrolidone, both substituted and unsubstituted formamides, both substituted and unsubstituted acetamides, and the like. Other examples of organic solvents or co-solvents include dimethyl sulfoxide (DMSO), isopropyl alcohol, ethanol, pentanol, acetone, or the like.

Some examples of suitable co-solvents include water-soluble high-boiling point solvents, which have a boiling point of at least 120° C., or higher. Some specific examples of high-boiling point solvents include 2-pyrrolidone (i.e., 2-pyrrolidinone, boiling point of about 245° C.), 1-methyl-2-pyrrolidone (boiling point of about 203° C.), N-(2-hydroxyethyl)-2-pyrrolidone (boiling point of about 140° C.), 2-methyl-1,3-propanediol (boiling point of about 212° C.), and combinations thereof.

The co-solvent(s) may be present in the ink in a total amount ranging from about 0.5 wt % to about 50 wt % based upon the total weight of the ink, depending upon the jetting architecture to be used to deposit the ink. In an example, the total amount of the co-solvent(s) present in the ink is about 1 wt % based on the total weight of the ink. In another example, the total amount of the co-solvent(s) present in the ink is about 20 wt % based on the total weight of the ink.

A disperant may be added to help form and maintain a dispersion of the conductive or semi-conductive or insulating material in the water-based vehicle. An example of a suitable dispersant includes one or more polycyclic aromatic compounds. The or each polycyclic aromatic compound has a ring system which includes from 2 to 6 fuzed benzene rings, and may have different hydrophilic groups (e.g., including less than 20 atoms) attached.

Whether a single dispersant is used or a combination of dispersants is used, the total amount of dispersant(s) in the ink may be 15 wt % or less, 5 wt % of less, or 1 wt5 or less, based on the total weight of the ink.

Examples of suitable surfactants include a self-emulsifiable, nonionic wetting agent based on acetylenic diol chemistry (e.g., SURFYNOL® SEF from Evonik Degussa), a nonionic fluorosurfactant (e.g., CAPSTONE® fluorosurfactants, such as CAPSTONE® FS-35, from The Chemours Co.), and combinations thereof. In other examples, the surfactant is an ethoxylated low-foam wetting agent (e.g., SURFYNOL® 440 or SURFYNOL® CT-111 from Evonik Degussa) or an ethoxylated wetting agent and molecular defoamer (e.g., SURFYNOL® 420 from Evonik Degussa). Still other suitable surfactants include non-ionic wetting agents and molecular defoamers (e.g., SURFYNOL® 104E from Evonik Degussa) or water-soluble, non-ionic surfactants (e.g., TERGITOL™ TMN-6, TERGITOL™ 15-S-7, or TERGITOL™ 15-S-9 (a secondary alcohol ethoxylate) from The Dow Chemical Company or TECO® Wet 510 (polyether siloxane) available from Evonik Degussa). Yet another suitable surfactant includes alkyldiphenyloxide disulfonate (e.g., the DOWFAX™ series, such a 2A1, 3B2, 8390, C6L, C10L, and 30599, from The Dow Chemical Company).

Whether a single surfactant is used or a combination of surfactants is used, the total amount of surfactant(s) in the ink may range from about 0.01 wt % to about 10 wt % active based on the total weight of the agent. In an example, the total amount of surfactant(s) in the ink may range from about 0.5 wt % active to about 1.5 wt % active based on the total weight of the ink.

An anti-kogation agent may be included in the ink that is to be jetted using thermal inkjet printing. Kogation refers to the deposit of dried ink on a heating element of a thermal inkjet printhead. Anti-kogation agent(s) is/are included to assist in preventing the buildup of kogation. Examples of suitable anti-kogation agents include oleth-3-phosphate (e.g., commercially available as CRODAFOS® O3A or CRODAFOS® N-3 acid from Croda), dextran 500k, CRODAFOS™ HCE (phosphate-ester from Croda Int.), CRODAFOS® N10 (oleth-10-phosphate from Croda Int.), DISPERSOGEN® LFH (polymeric dispersing agent with aromatic anchoring groups, acid form, anionic, from Clariant), or a combination of oleth-3-phosphate and a low molecular weight (e.g., <5,000) acrylic acid polymer (e.g., commercially available as CARBOSPERSE™ K-7028 Polyacrylate from Lubrizol).

Whether a single anti-kogation agent is used or a combination of anti-kogation agents is used, the total amount of anti-kogation agent(s) in the ink may range from about 0.1 wt % active to about 5 wt % active based on the total weight of the ink. In an example, the anti-kogation agent may be present in an amount ranging from greater than 0.1 wt % active to about 1.5 wt % active.

The water-based ink may also include antimicrobial agent(s). Suitable antimicrobial agents include biocides and fungicides. Example antimicrobial agents may include the NUOSEPT™ (Troy Corp.), UCARCIDE™ (The Dow Chemical Company), ACTICIDE® B20 (Thor Chemicals), ACTICIDE® M20 (Thor Chemicals), ACTICIDE® MBL (blends of 2-methyl-4-isothiazolin-3-one (MIT), 1,2-benzisothiazolin-3-one (BIT) and Bronopol) (Thor Chemicals), AXIDE™ (Planet Chemical), NIPACIDE™ (Clariant), blends of 5-chloro-2-methyl-4-isothiazolin-3-one (CIT or CMIT) and MIT under the tradename KATHON™ (The Dow Chemical Company), and combinations thereof. Examples of suitable biocides include an aqueous solution of 1,2-benzisothiazolin-3-one (e.g., PROXEL® GXL from Arch Chemicals, Inc.), quaternary ammonium compounds (e.g., BARDAC® 2250 and 2280, BARQUAT® 50-65B, and CARBOQUAT® 250-T, all from Lonza Ltd. Corp.), and an aqueous solution of methylisothiazolone (e.g., KORDEK® MLX from The Dow Chemical Company).

In an example, the ink may include a total amount of antimicrobial agent(s) that ranges from about 0.0001 wt % active to about 1 wt % active. In an example, the antimicrobial agent(s) is/are a biocide(s) and is/are present in the ink in an amount of about 0.18 wt % active (based on the total weight of the ink).

The ink may also include humectant(s). In an example, the total amount of the humectant(s) present in the ink ranges from about 3 wt % active to about 10 wt % active, based on the total weight of the ink. An example of a suitable humectant is ethoxylated glycerin having the following formula:

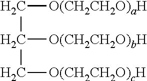

in which the total of a+b+c ranges from about 5 to about 60, or in other examples, from about 20 to about 30. An example of the ethoxylated glycerin is LIPON IC® EG-1 (LEG-1, glycereth-26, a+b+c=26, available from Lipo Chemicals).

Chelating agents (or sequestering agents) may also be included in the ink to eliminate the deleterious effects of heavy metal impurities and/or to capture any soluble metal ions in the conductive agent. Examples of chelating agents include disodium ethylenediaminetetraacetic acid (EDTA-Na), ethylene diamine tetra acetic acid (EDTA), and methylglycinediacetic acid (e.g., TRILON® M from BASF Corp.).

Whether a single chelating agent is used or a combination of chelating agents is used, the total amount of chelating agent(s) in the ink may range from greater than 0 wt % active to about 2 wt % active based on the total weight of the ink. In an example, the chelating agent(s) is/are present in the ink in an amount of about 0.08 wt % active (based on the total weight of the ink).

Any suitable viscosity (rheology) modifier may be used. Water soluble polymers (e.g., polyethylene glycol) may be suitable rheology modifiers. While one example has been provided, it is to be understood that other suitable inkjet rheology modifiers may be used. The amount added may depend upon the desired viscosity for the ink.

Any suitable surface tension modifier may be used. In some instances, the surfactants disclosed herein may be used to modify the surface tension of the ink. It is to be further understood that other suitable surface tension modifiers may be used. The amount added may depend upon the desired surface tension for the ink.

The pH of the ink may be neutral (e.g., about 7). A pH adjuster may be included in the ink to achieve a desired pH.

The type and amount of pH adjuster that is added to the ink may depend upon the initial pH of the ink and the desired final pH of the ink. If the initial pH is too high, an acid may be added to lower the pH, and if the initial pH is too low, a base may be added increase the pH. An example of a suitable acid includes methanesulfonic acid, sulfuric acid and nitric acid. Examples of suitable bases include metal hydroxide bases, such as potassium hydroxide (KOH), sodium hydroxide (NaOH), lithium hydroxide (LiOH), tetraalkylammonium hydroxide (R₄NOH), etc. In an example, the acid or base may be added to the conductive ink in an aqueous solution. As examples, the methanesulfonic acid may be added to the ink in an aqueous solution including 70 wt % of the acid, or the metal hydroxide base may be added to the conductive ink in an aqueous solution including 5 wt % of the metal hydroxide base (e.g., a 5 wt % potassium hydroxide aqueous solution).

In an example, the total amount of pH adjuster(s) in the ink ranges from greater than 0 wt % active to about 2 wt % active (based on the total weight of the conductive ink). In another example, the total amount of pH adjuster(s) in the conductive ink ranges from about 0.03 wt % active to about 0.1 wt % active (based on the total weight of the conductive ink).

The ink may also include a buffer to prevent undesirable changes in the pH. Examples of buffers include TRIS (tris(hydroxymethyl)aminomethane or TRIZMA®), bis-tris propane, TES (2-[(2-Hydroxy-1,1-bis(hydroxymethyl)ethyl)amino]ethanesulfonic acid), MES (2-ethanesulfonic acid), MOPS (3-(N-morpholino)propanesulfonic acid), HEPES (4-(2-hydroxyethyl)-1-piperazineethanesulfonic acid), DIPSO (3-(N,N-Bis[2-hydroxyethyl]amino)-2-hydroxypropanesulfonic acid), Tricine (N-[tris(hydroxymethyl)methyl]glycine), HEPPSO (β-Hydroxy-4-(2-hydroxyethyl)-1-piperazinepropanesulfonic acid monohydrate), POPSO (Piperazine-1,4-bis(2-hydroxypropanesulfonic acid) dihydrate), EPPS (4-(2-Hydroxyethyl)-1-piperazinepropanesulfonic acid, 4-(2-Hydroxyethyl)piperazine-1-propanesulfonic acid), TEA (triethanolamine buffer solution), Gly-Gly (Diglycine), bicine (N,N-Bis(2-hydroxyethyl)glycine), HEPBS (N-(2-Hydroxyethyl)piperazine-N′-(4-butanesulfonic acid)), TAPS ([tris(hydroxymethyl)methylamino]propanesulfonic acid), AMPD (2-amino-2-methyl-1,3-propanediol), TABS (N-tris(Hydroxymethyl)methyl-4-aminobutanesulfonic acid), or the like.

Whether a buffer is used or a combination of buffers is used, the total amount of buffer(s) in the ink may range from greater than 0 wt % active to about 0.5 wt % active based on the total weight of the ink. In an example, the buffer(s) is/are present in the ink in an amount of about 0.1 wt % active (based on the total weight of the ink).

When any or all of these additives are included in the ink, it is to be understood that the balance of the ink is water. As such, the amount of water may vary depending upon the amounts of the other components that are included. In an example, deionized water or purified water may be used.

In some examples, the ink is jettable via thermal inkjet printing, piezoelectric inkjet printing, continuous inkjet printing, or a combination thereof. As such, the liquid components may be selected to achieve the desired jettability. For example, if the conductive ink is to be jettable via thermal inkjet printing, water may make up from about 35 wt % to about 90 wt % of the ink. For another example, if the ink is to be jettable via piezoelectric inkjet printing, water may make up from about 25 wt % to about 30 wt % of the conductive agent, and 35 wt % or more of the conductive agent may be the organic co-solvent. For still another example, if the ink is to be jettable via piezoelectric inkjet printing, water may make up more than 90 wt % of the ink.

Inkjet Printing and Other Techniques

An example of a method includes inkjet printing a water-based ink directly on a non-conductive, graphene oxide membrane base substrate 12 to form a flexible printed article. To form the flexible printed article 10, which includes the printed electronic component 14, the water-based ink is an example of the conductive, semi-conductive, or insulting ink disclosed herein. In this example, the solids of the printed ink form the electronic component 14.

The ink may be dispensed from an applicator, such as a thermal inkjet printhead, a piezoelectric printhead, a continuous inkjet printhead, etc. A controller may process data regarding the shape, size, etc. of the electronic component 14 that is being formed, and in response, controls the applicator to deposit the ink onto predetermined portion(s) of the non-conductive, graphene oxide membrane base substrate 12.

In other examples, the water-based ink is directly applied on the non-conductive, graphene oxide membrane base substrate 12 using another suitable deposition technique, such as spray coating, screen printing, etc.

After the ink is applied to the non-conductive, graphene oxide membrane base substrate 12, the conductive ink may be dried. In an example, the conductive ink may dry at room temperature (i.e., 18° C. to 22° C.). In other examples, a slightly elevated heating temperature, but less than 50° C., may be used for drying.

In addition to being a suitable substrate for printed electronic components 14, the non-conductive, graphene oxide membrane base substrate 12 may also be suitable for use in other inkjet printing applications. For example, colored inkjet inks may be printed on the conductive, graphene oxide membrane base substrate 12 to form images (e.g., text, picture, etc.). Because the non-conductive, graphene oxide membrane base substrates 12 disclosed herein are black or grey in color, they may be particularly desirable as paper-like substrates for white inks, or other colored inks (e.g., cyan, magenta, yellow, etc.) deposited on top of white inks. In these examples, the printing method includes inkjet printing a colored water-based ink directly on a graphene oxide membrane (e.g., substrate 12).

Colored water-based inks include a colorant and a liquid vehicle in which the colorant is dispersed. In some instances, colored inks may also include polymeric binders and/or polymeric dispersants. Examples of binders and/or dispersant include acrylics (e.g., water-soluble acrylic acid polymers, such as CARBOSPERSE® K7028 available from Lubrizol; or water-soluble styrene-acrylic acid copolymers/resins, such as JONCRYL® 296, JONCRYL® 671, JONCRYL® 678, JONCRYL® 680, JONCRYL® 683, JONCRYL® 690, etc. available from BASF Corp.); high molecular weight block copolymers with pigment affinic groups, such as DISPERBYK®-190 available from BYK Additives and Instruments; water-soluble styrene-maleic anhydride copolymers/resins; polyurethanes; or the like.

The colorant may be a pigment. The pigment used will depend upon the desired color for the colored ink. White inks may include any suitable white pigment (e.g., white metal oxide pigments, such as titanium dioxide (TiO₂), zinc oxide (ZnO), zirconium dioxide (ZrO₂), or white metal oxide pigment particles coated with silicon dioxide (SiO₂) and/or aluminum oxide (Al₂O₃)). Any suitable blue and/or cyan organic pigment may be used for a cyan ink; any suitable magenta, red, and/or violet organic pigments may be used for a magenta ink; and any suitable yellow organic pigment may be used for a yellow ink.

The liquid vehicle of the colored inks may include water and any one or more of the additives (e.g., co-solvents, surfactants, antimicrobial agents, anti-kogation agents, etc.) disclosed herein for the conductive ink.

In example colored ink formulations, the colorant may be present in an amount ranging from about 1 wt % active to about 10 wt % active, the polymeric binder and/or polymeric dispersant may be present in an amount ranging from about 2 wt % active to about 15 wt % active, any one or more of the additives (e.g., co-solvents, surfactants, antimicrobial agents, anti-kogation agents, etc.) in any of the amounts set forth herein for the conductive ink, and a balance of water.

The colored water-based inks may be dispensed from any of the applicators disclosed herein. Once printed on the graphene oxide membrane, the colored water-based inks may be dried using any technique described herein for the conductive ink.

Three Dimensional Printing

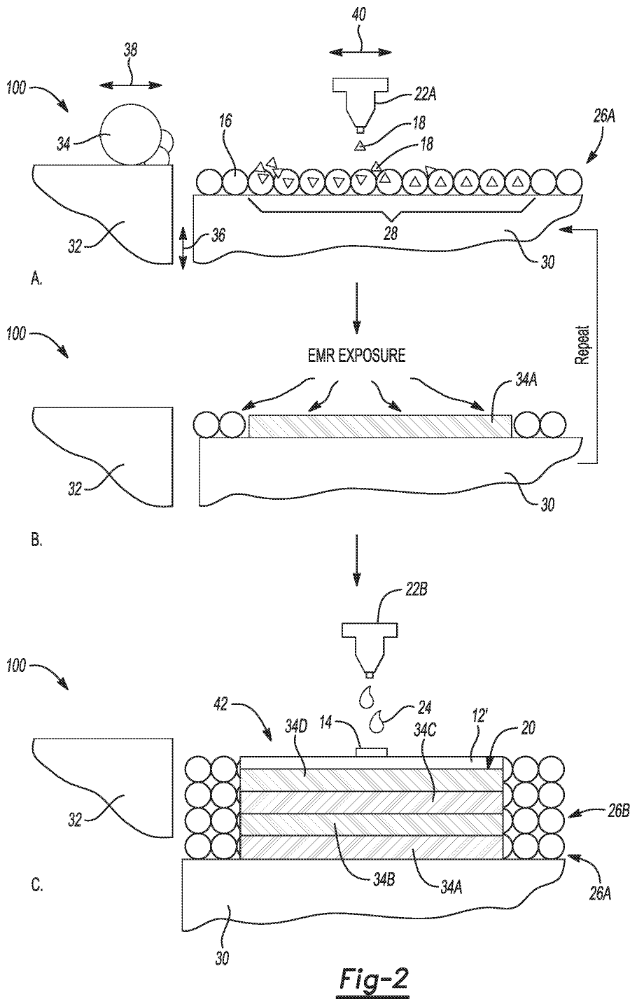

The flexible printed article 10 may also be generated during a three-dimensional (3D) printing process so that it is part of a 3D printed object. An example of the 3D printing process 100 is shown schematically in FIG. 2. The 3D printing process 100 involves patterning build material 16 with a fusing agent 18. Examples of each of these components will now be described.

Polymeric Build Material

Any polymeric build material 16 that, when fused, has a similarly bendability to the graphene oxide membrane disclosed herein may be used. Examples of suitable polymeric materials include a polyamide (PAs) (e.g., PA 11/nylon 11, PA 12/nylon 12, PA 6/nylon 6, PA 8/nylon 8, PA 9/nylon 9, PA 66/nylon 66, PA 612/nylon 612, PA 812/nylon 812, PA 912/nylon 912, etc.), a thermoplastic polyamide (TPA), a thermoplastic polyurethane (TPU), a styrenic block copolymer (TPS), a thermoplastic polyolefin elastomer (TPO), a thermoplastic vulcanizate (TPV), thermoplastic copolyester (TPC), a polyether block amide (PEBA), and a combination thereof.

In some examples, the polymeric build material 16 may be in the form of a powder. In other examples, the polymeric build material 16 may be in the form of a powder-like material, which includes, for example, short fibers having a length that is greater than its width. In some examples, the powder or powder-like material may be formed from, or may include, short fibers that may, for example, have been cut into short lengths from long strands or threads of material.

The polymeric build material 16 may be made up of similarly sized particles and/or differently sized particles. In an example, the average particle size of the polymeric build material 16 ranges from about 2 μm to about 225 μm. In another example, the average particle size of the polymeric build material 16 ranges from about 10 μm to about 130 μm. The term “average particle size”, as used herein, may refer to a number-weighted mean diameter or a volume-weighted mean diameter of a particle distribution.

When the polymeric build material 16 is a polyamide, the polymer may have a wide processing window of greater than 5° C., which can be defined by the temperature range between the melting point and the re-crystallization temperature. In an example, the polymer may have a melting point ranging from about 50° C. to about 300° C. As other examples, the polymer may have a melting point ranging from about 155° C. to about 225° C., from about 155° C. to about 215° C., about 160° C. to about 200° C., from about 170° C. to about 190° C., or from about 182° C. to about 189° C. As still another example, the polymer may be a polyamide having a melting point of about 180° C.

When the polymeric build material 16 is a thermoplastic elastomer, the thermoplastic elastomer may have a melting range within the range of from about 130° C. to about 250° C. In some examples (e.g., when the thermoplastic elastomer is a polyether block amide), the thermoplastic elastomer may have a melting range of from about 130° C. to about 175° C. In some other examples (e.g., when the thermoplastic elastomer is a thermoplastic polyurethane), the thermoplastic elastomer may have a melting range of from about 130° C. to about 180° C. or a melting range of from about 175° C. to about 210° C.

In some examples, the polymeric build material 16 does not substantially absorb radiation having a wavelength within the range of 300 nm to 1400 nm. The phrase “does not substantially absorb” means that the absorptivity of the thermoplastic elastomer at a particular wavelength is 25% or less (e.g., 20%, 10%, 5%, etc.)

In some examples, in addition to the polymeric build material 16, the build material composition may include an antioxidant, a whitener, an antistatic agent, a flow aid, or a combination thereof. While several examples of these additives are provided, it is to be understood that these additives are selected to be thermally stable (i.e., will not decompose) at the 3D printing temperatures.

Antioxidant(s) may be added to the build material composition to prevent or slow molecular weight decreases of the polymeric build material 16 and/or may prevent or slow discoloration (e.g., yellowing) of the polymeric build material 16 by preventing or slowing oxidation of the polymeric build material 16. In some examples, the antioxidant may discolor upon reacting with oxygen, and this discoloration may contribute to the discoloration of the build material composition. The antioxidant may be selected to minimize discoloration. In some examples, the antioxidant may be a radical scavenger. In these examples, the antioxidant may include IRGANOX® 1098 (benzenepropanamide, N,N′-1,6-hexanediylbis(3,5-bis(1,1-dimethylethyl)-4-hydroxy)), IRGANOX® 254 (a mixture of 40% triethylene glycol bis(3-tert-butyl-4-hydroxy-5-methylphenyl), polyvinyl alcohol and deionized water), and/or other sterically hindered phenols. In other examples, the antioxidant may include a phosphite and/or an organic sulfide (e.g., a thioester). The antioxidant may be in the form of fine particles (e.g., having an average particle size of 5 μm or less) that are dry blended with the polymeric build material 16. In an example, the antioxidant may be included in the build material composition in an amount ranging from about 0.01 wt % to about 5 wt %, based on the total weight of the build material composition. In other examples, the antioxidant may be included in the build material composition in an amount ranging from about 0.01 wt % to about 2 wt % or from about 0.2 wt % to about 1 wt %, based on the total weight of the build material composition.

Whitener(s) may be added to the build material composition to improve visibility. Examples of suitable whiteners include titanium dioxide (TiO₂), zinc oxide (ZnO), calcium carbonate (CaCO₃), zirconium dioxide (ZrO₂), aluminum oxide (Al₂O₃), silicon dioxide (SiO₂), boron nitride (BN), and combinations thereof. In some examples, a stilbene derivative may be used as the whitener and a brightener. In these examples, the temperature(s) of the 3D printing process may be selected so that the stilbene derivative remains stable (i.e., the 3D printing temperature does not thermally decompose the stilbene derivative). In an example, any example of the whitener may be included in the build material composition in an amount ranging from greater than 0 wt % to about 10 wt %, based on the total weight of the build material composition.

Antistatic agent(s) may be added to the build material composition to suppress tribo-charging. Examples of suitable antistatic agents include aliphatic amines (which may be ethoxylated), aliphatic amides, quaternary ammonium salts (e.g., behentrimonium chloride or cocamidopropyl betaine), esters of phosphoric acid, polyethylene glycolesters, or polyols. Some suitable commercially available antistatic agents include HOSTASTAT® FA 38 (natural based ethoxylated alkylamine), HOSTASTAT® FE2 (fatty acid ester), and HOSTASTAT® HS 1 (alkane sulfonate), each of which is available from Clariant Int. Ltd.). In an example, the antistatic agent is added in an amount ranging from greater than 0 wt % to less than 5 wt %, based upon the total weight of the build material composition.

Flow aid(s) may be added to improve the coating flowability of the build material composition. Flow aids may be particularly beneficial when the build material composition has an average particle size less than 25 μm. The flow aid improves the flowability of the build material composition by reducing the friction, the lateral drag, and the tribocharge buildup (by increasing the particle conductivity). Examples of suitable flow aids include aluminum oxide (Al₂O₃), tricalcium phosphate (E341), powdered cellulose (E460(ii)), magnesium stearate (E470b), sodium bicarbonate (E500), sodium ferrocyanide (E535), potassium ferrocyanide (E536), calcium ferrocyanide (E538), bone phosphate (E542), sodium silicate (E550), silicon dioxide (E551), calcium silicate (E552), magnesium trisilicate (E553a), talcum powder (E553b), sodium aluminosilicate (E554), potassium aluminum silicate (E555), calcium aluminosilicate (E556), bentonite (E558), aluminum silicate (E559), stearic acid (E570), and polydimethylsiloxane (E900). In an example, the flow aid is added in an amount ranging from greater than 0 wt % to less than 5 wt %, based upon the total weight of the build material composition.

Fusing Agent

During the 3D printing process 100, the fusing agent 18 may be applied wherever it is desirable to coalesce the polymeric build material 16. The fusing agent 18 includes an energy absorber that enhances the absorption of radiation, converts the absorbed radiation to thermal energy, and promotes the transfer of the thermal heat to the polymeric build material 16 in contact therewith.

The energy absorber may have substantial absorption (e.g., 80%) at least in the visible region (400 nm-780 nm) and may have substantial absorption in the infrared region (e.g., 800 nm to 4000 nm). In other examples, the energy absorber may have substantial absorption at wavelengths ranging from 800 nm to 4000 nm and have transparency at wavelengths ranging from 400 nm to 780 nm. As used herein, “substantial absorption” means that at least 80% of radiation having wavelengths within the specified range is absorbed. Also as used herein, “transparency” means that 25% or less of radiation having wavelengths within the specified range is absorbed.

In some examples, the energy absorber may be an infrared light absorbing colorant. In an example, the energy absorber is a near-infrared light absorbing colorant. Any near-infrared colorants, e.g., those produced by Fabricolor, Eastman Kodak, or BASF, Yamamoto, may be used in the fusing agent. As one example, the fusing agent may be a printing liquid formulation including carbon black as the energy absorber. Examples of this printing liquid formulation are commercially known as CM997A, 516458, C18928, C93848, C93808, or the like, all of which are available from HP Inc.

As another example, the energy absorber may be a near-infrared absorbing dye. Examples of printing liquid formulations including these types of dyes are described in U.S. Pat. No. 9,133,344, incorporated herein by reference in its entirety. Some examples of the near-infrared absorbing dye are water-soluble near-infrared absorbing dyes selected from the group consisting of:

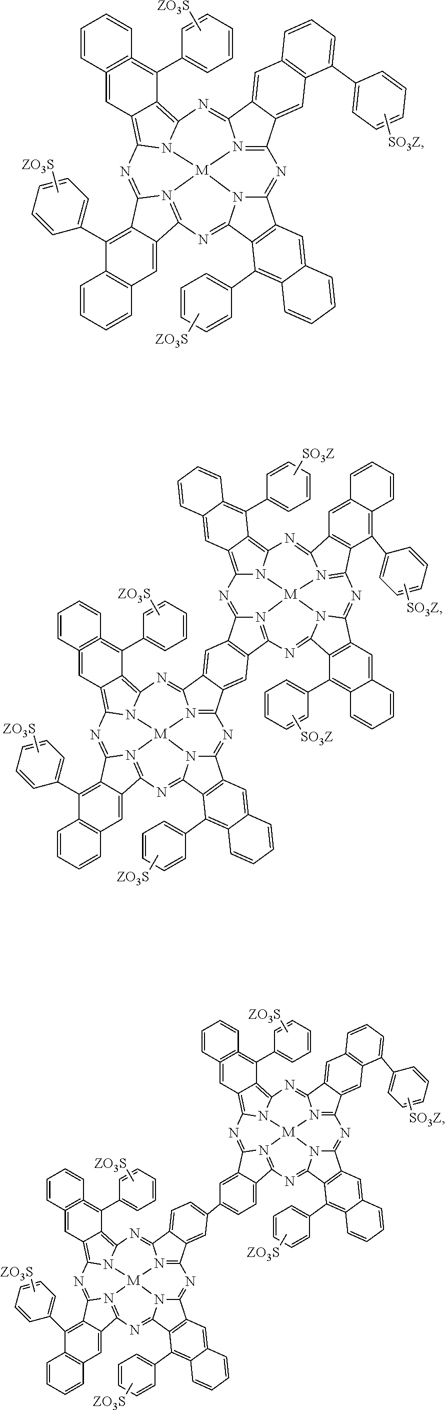

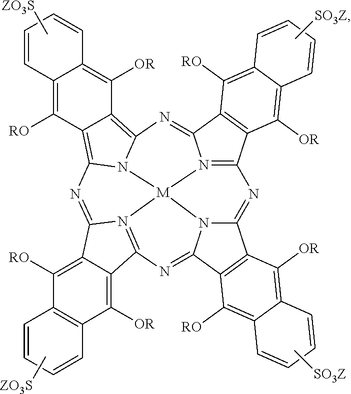

and mixtures thereof. In the above structures, M can be a divalent metal atom (e.g., copper, etc.) or can have OSO₃Na axial groups filling any unfilled valencies if the metal is more than divalent (e.g., indium, etc.), R can be hydrogen or any C₁-C₈ alkyl group (including substituted alkyl and unsubstituted alkyl), and Z can be a counterion such that the overall charge of the near-infrared absorbing dye is neutral. For example, the counterion can be sodium, lithium, potassium, NH₄⁺, etc.

Some other examples of the near-infrared absorbing dye are hydrophobic near-infrared absorbing dyes selected from the group consisting of:

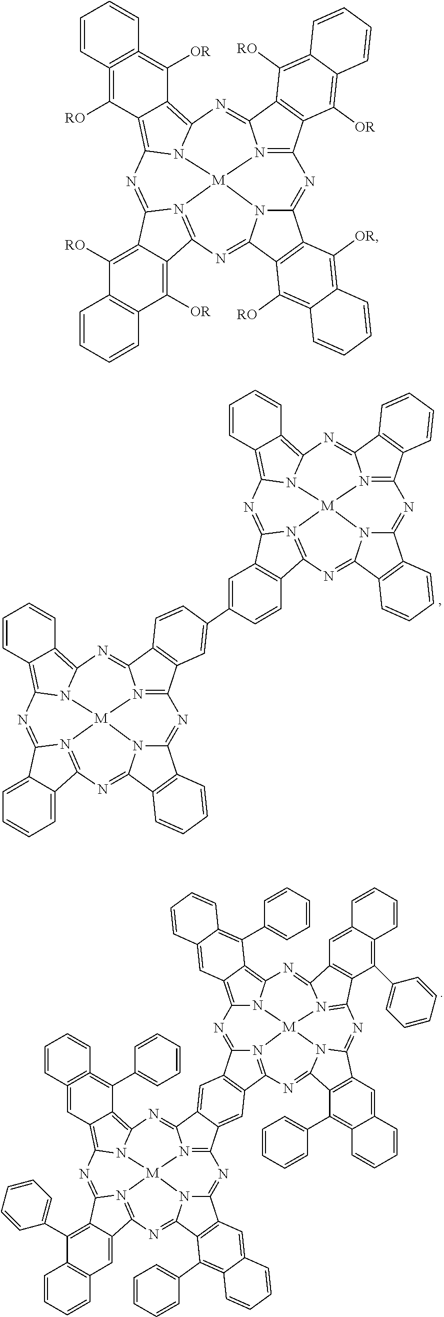

and mixtures thereof. For the hydrophobic near-infrared absorbing dyes, M can be a divalent metal atom (e.g., copper, etc.) or can include a metal that has Cl, Br, or OR′ (R′═H, CH₃, COCH₃, COCH₂COOCH₃, COCH₂COCH₃) axial groups filling any unfilled valencies if the metal is more than divalent, and R can be hydrogen or any C₁-C₈ alkyl group (including substituted alkyl and unsubstituted alkyl).

Other near-infrared absorbing dyes or pigments may be used. Some examples include anthroquinone dyes or pigments, metal dithiolene dyes or pigments, cyanine dyes or pigments, perylenediimide dyes or pigments, croconium dyes or pigments, pyrilium or thiopyrilium dyes or pigments, boron-dipyrromethene dyes or pigments, or aza-boron-dipyrromethene dyes or pigments.

Anthroquinone dyes or pigments and metal (e.g., nickel) dithiolene dyes or pigments may have the following structures, respectively:

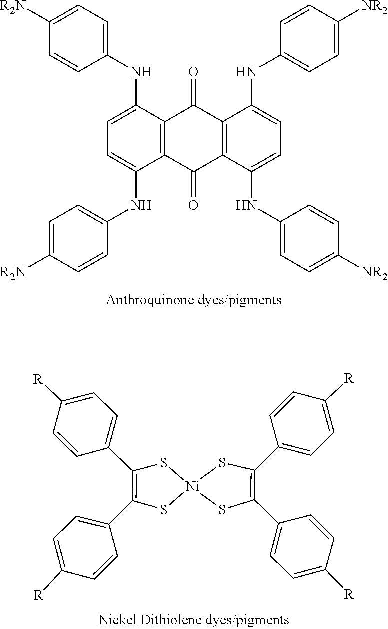

where R in the anthroquinone dyes or pigments may be hydrogen or any C₁-C₈ alkyl group (including substituted alkyl and unsubstituted alkyl), and R in the dithiolene may be hydrogen, COOH, SO₃, NH₂, any C₁-C₈ alkyl group (including substituted alkyl and unsubstituted alkyl), or the like.

Cyanine dyes or pigments and perylenediimide dyes or pigments may have the following structures, respectively:

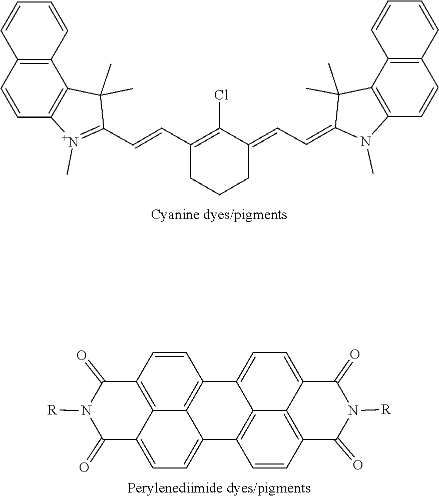

where R in the perylenediimide dyes or pigments may be hydrogen or any C₁-C₈ alkyl group (including substituted alkyl and unsubstituted alkyl).

Croconium dyes or pigments and pyrilium or thiopyrilium dyes or pigments may have the following structures, respectively:

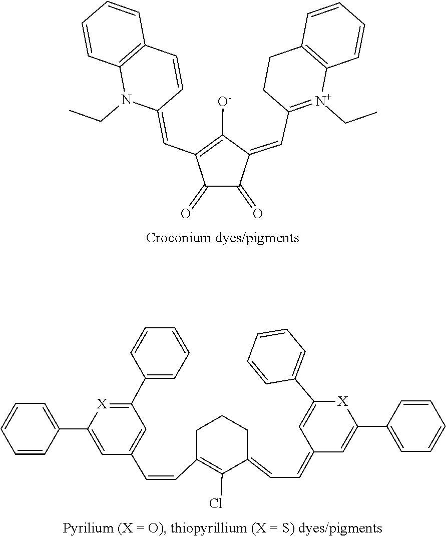

Boron-dipyrromethene dyes or pigments and aza-boron-dipyrromethene dyes or pigments may have the following structures, respectively:

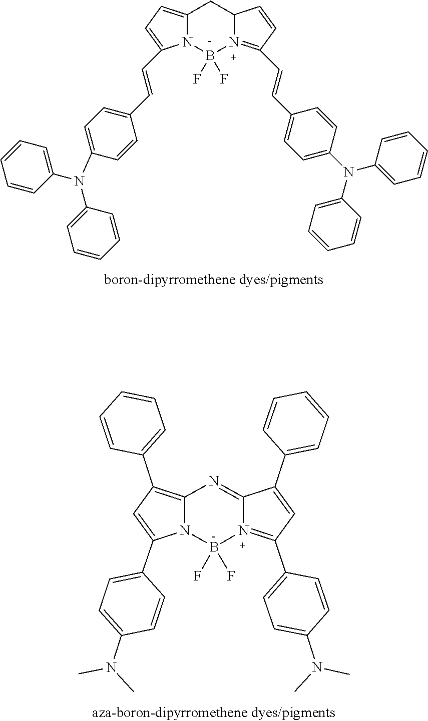

In other examples, the energy absorber may be the energy absorber that has absorption at wavelengths ranging from 800 nm to 4000 nm and transparency at wavelengths ranging from 400 nm to 780 nm. The absorption of this energy absorber is the result of plasmonic resonance effects. Electrons associated with the atoms of the energy absorber may be collectively excited by radiation, which results in collective oscillation of the electrons. The wavelengths that can excite and oscillate these electrons collectively are dependent on the number of electrons present in the energy absorber particles, which in turn is dependent on the size of the energy absorber particles. The amount of energy that can collectively oscillate the particle's electrons is low enough that very small particles (e.g., 1-100 nm) may absorb radiation with wavelengths several times (e.g., from 8 to 800 or more times) the size of the particles. The use of these particles allows the fusing agent to be inkjet jettable as well as electromagnetically selective (e.g., having absorption at wavelengths ranging from 800 nm to 4000 nm and transparency at wavelengths ranging from 400 nm to 780 nm).

In an example, this energy absorber has an average particle diameter (e.g., volume-weighted mean diameter) ranging from greater than 0 nm to less than 220 nm. In another example, the energy absorber has an average particle diameter ranging from greater than 0 nm to 120 nm. In a still another example, the energy absorber has an average particle diameter ranging from about 10 nm to about 200 nm.

In an example, this energy absorber is an inorganic pigment. Examples of suitable inorganic pigments include lanthanum hexaboride (LaB₆), tungsten bronzes (AₓWO₃), indium tin oxide (In₂O₃:SnO₂, ITO), antimony tin oxide (Sb₂O₃:SnO₂, ATO), titanium nitride (TiN), aluminum zinc oxide (AZO), ruthenium oxide (RuO₂), silver (Ag), gold (Au), platinum (Pt), iron pyroxenes (AₓFe_{y}Si₂O₆ wherein A is Ca or Mg, x=1.5-1.9, and y=0.1-0.5), modified iron phosphates (AₓFe_{y}PO₄), modified copper phosphates (AₓCu_{y}PO_{z}), and modified copper pyrophosphates (AₓCu_{y}P₂O₇). Tungsten bronzes may be alkali doped tungsten oxides. Examples of suitable alkali dopants (i.e., A in AₓWO₃) may be cesium, sodium, potassium, or rubidium. In an example, the alkali doped tungsten oxide may be doped in an amount ranging from greater than 0 mol % to about 0.33 mol % based on the total mol % of the alkali doped tungsten oxide. Suitable modified iron phosphates (AₓFe_{y}PO) may include copper iron phosphate (A=Cu, x=0.1-0.5, and y=0.5-0.9), magnesium iron phosphate (A=Mg, x=0.1-0.5, and y=0.5-0.9), and zinc iron phosphate (A=Zn, x=0.1-0.5, and y=0.5-0.9). For the modified iron phosphates, it is to be understood that the number of phosphates may change based on the charge balance with the cations. Suitable modified copper pyrophosphates (AₓCu_{y}P₂O₇) include iron copper pyrophosphate (A=Fe, x=0-2, and y=0-2), magnesium copper pyrophosphate (A=Mg, x=0-2, and y=0-2), and zinc copper pyrophosphate (A=Zn, x=0-2, and y=0-2). Combinations of the inorganic pigments may also be used.

The amount of the energy absorber that is present in the fusing agent ranges from greater than 0 wt % active to about 40 wt % active based on the total weight of the fusing agent. In other examples, the amount of the energy absorber in the fusing agent ranges from about 0.3 wt % active to 30 wt % active, from about 1 wt % active to about 20 wt % active, from about 1.0 wt % active up to about 10.0 wt % active, or from greater than 4.0 wt % active up to about 15.0 wt % active. It is believed that these energy absorber loadings provide a balance between the fusing agent having jetting reliability and heat and/or radiation absorbance efficiency.

The energy absorber is dispersed or dissolved in a fusing agent (FA) vehicle. A wide variety of FA vehicles, including aqueous and non-aqueous solvents, may be used in the fusing agent 18.

The solvent of the fusing agent 18 may be water or a non-aqueous solvent (e.g., ethanol, acetone, n-methyl pyrrolidone, aliphatic hydrocarbons, etc.). In some examples, the fusing agent 18 consists of the energy absorber and the solvent (without other components). In these examples, the solvent makes up the balance of the fusing agent. In other examples, the FA vehicle may include other components, depending, in part, upon the applicator 22A (see FIG. 2, at A) that is to be used to dispense the fusing agent 18. Examples of other suitable fusing agent components include dispersant(s), silane coupling agent(s), co-solvent(s), humectant(s), surfactant(s), antimicrobial agent(s), anti-kogation agent(s), and/or chelating agent(s). In some examples, the FA vehicle may be similar to the water-based vehicle of the conductive ink 24 (see FIG. 2, at C). As such, the FA vehicle of the fusing agent 18 may include any of the components described above in reference to the conductive ink in any of the amount described above (with the amount(s) being based on the total weight of the fusing agent 18 rather than the total weight of the conductive ink 24).

When energy absorber is an inorganic pigment (having absorption at wavelengths ranging from 800 nm to 4000 nm and transparency at wavelengths ranging from 400 nm to 780 nm), the FA vehicle may also include dispersant(s) and/or silane coupling agent(s).

The dispersant helps to uniformly distribute the energy absorber throughout the fusing agent 18. Examples of suitable dispersants include polymer or small molecule dispersants, charged groups attached to the energy absorber surface, or other suitable dispersants. Some specific examples of suitable dispersants include a water-soluble acrylic acid polymer (e.g., CARBOSPERSE® K7028 available from Lubrizol), water-soluble styrene-acrylic acid copolymers/resins (e.g., JONCRYL® 296, JONCRYL® 671, JONCRYL® 678, JONCRYL® 680, JONCRYL® 683, JONCRYL® 690, etc. available from BASF Corp.), a high molecular weight block copolymer with pigment affinic groups (e.g., DISPERBYK®-190 available BYK Additives and Instruments), or water-soluble styrene-maleic anhydride copolymers/resins.

Whether a single dispersant is used or a combination of dispersants is used, the total amount of dispersant(s) in the fusing agent 18 may range from about 10 wt % to about 200 wt % based on the weight of the energy absorber in the fusing agent.

A silane coupling agent may also be added to the fusing agent 18 to help bond the organic and inorganic materials. Examples of suitable silane coupling agents include the SILQUEST® A series manufactured by Momentive.

Whether a single silane coupling agent is used or a combination of silane coupling agents is used, the total amount of silane coupling agent(s) in the fusing agent may range from about 0.1 wt % active to about 50 wt % active based on the weight of the energy absorber in the fusing agent. In an example, the total amount of silane coupling agent(s) in the fusing agent ranges from about 1 wt % active to about 30 wt % active based on the weight of the energy absorber. In another example, the total amount of silane coupling agent(s) in the fusing agent ranges from about 2.5 wt % active to about 25 wt % active based on the weight of the energy absorber.

3D Printing Method

Referring now specifically to FIG. 2, the 3D printing method 100 includes forming a base structure 20 by iteratively applying layers 26A, 26B of a polymeric build material 16; patterning at least a portion 28 of each layer with a fusing agent 18; and exposing each layer to electromagnetic radiation (EMR), thereby coalescing the at least the portion 28 of each layer 26A, 26B; applying a graphene oxide membrane 12′ on the base structure 20; and depositing a water-based, conductive ink 24 on at least a portion of the graphene oxide membrane 12′, thereby forming a printed electronic device 14.

A controller may access data stored in a data store pertaining to a 3D object that is to be printed. For example, the controller may determine the number of layers 26A, 26B of the polymeric build material 16 that are to be formed for the base structure 20, the locations at which the fusing agent 18 is to be deposited on each of the respective layers from the applicator(s) 24, etc.

In FIG. 2, at A and B, a layer 26A of the polymeric build material 16 is applied on a build area platform 30. As mentioned above, the polymeric build material 16 may be mixed with the antioxidant, the whitener, the antistatic agent, the flow aid, or combinations thereof.

In the example shown in FIG. 2, a printing system may be used to apply the polymeric build material 16. The printing system may include a build area platform 30, a build material supply 32 containing the polymeric build material 16, and a build material distributor 34.

The build area platform 32 receives the polymeric build material 16 from the build material supply 32. The build area platform 30 may be moved in the directions as denoted by the arrow 36, e.g., along the z-axis, so that the polymeric build material 16 may be delivered to the build area platform 30 or to a previously formed layer (e.g., layer 34A). In an example, when the polymeric build material 16 is to be delivered, the build area platform 30 may be programmed to advance (e.g., downward) enough so that the build material distributor 34 can push the polymeric build material 16 onto the build area platform 30 to form a substantially uniform layer of the polymeric build material 16 thereon. The build area platform 12 may also be returned to its original position, for example, when a new part is to be built.

The build material supply 32 may be a container, bed, or other surface that is to position the polymeric build material 16 between the build material distributor 34 and the build area platform 30. In some examples, the method 100 further includes heating the polymeric build material 16 in the build material supply 32 to a supply temperature ranging from about 40° C. to about 100° C. In these examples, the supply temperature may depend, in part, on the polymeric build material 16 used and/or the 3D printer used. The heating of the polymeric build material 16 in the build material supply 32 may be accomplished by heating the build material supply 32 to the supply temperature.

The build material distributor 34 may be moved in the directions as denoted by the arrow 38, e.g., along the y-axis, over the build material supply 32 and across the build area platform 30 to spread the layer 26A of the polymeric build material 16 over the build area platform 30. The build material distributor 34 may also be returned to a position adjacent to the build material supply 32 following the spreading of the polymeric build material 16. The build material distributor 34 may be a blade (e.g., a doctor blade), a roller, a combination of a roller and a blade, and/or any other device capable of spreading the polymeric build material 16 over the build area platform 30. For instance, the build material distributor 34 may be a counter-rotating roller. In some examples, the build material supply 32 or a portion of the build material supply 32 may translate along with the polymeric build material 16 such that polymeric build material 16 is delivered continuously to the material distributor 34 rather than being supplied from a single location at the side of the printing system as depicted in FIG. 2.

In FIG. 2, the build material supply 32 may supply polymeric build material 16 into a position so that it is ready to be spread onto the build area platform 30. The build material distributor 34 may spread the supplied polymeric build material 16 onto the build area platform 30. The controller may process data, and in response, control the build material supply 32 to appropriately position the particles of the polymeric build material 16, and may process additional data, and in response, control the build material distributor 34 to spread the supplied polymeric build material 16 over the build area platform 30 to form the layer 26A of polymeric build material 16 thereon. As shown in FIG. 2, at A, one build material layer 26A has been formed.

The layer 26A of the polymeric build material 16 has a substantially uniform thickness across the build area platform 30. In an example, the build material layer 26A has a thickness ranging from about 50 μm to about 120 μm. In another example, the thickness of the build material layer 26A ranges from about 30 μm to about 300 μm. It is to be understood that thinner or thicker layers may also be used. For example, the thickness of the build material layer 26A may range from about 20 μm to about 500 μm. The layer thickness may be about 2× (i.e., 2 times) the average diameter of the build material composition particles at a minimum for finer part definition. In some examples, the layer thickness may be about 1.2× the average diameter of the build material composition particles.

After the polymeric build material 16 has been applied, and prior to further processing, the build material layer 26A may be exposed to heating. Heating may be performed to pre-heat the polymeric build material 16, and thus the heating temperature may be below the melting point or the lowest temperature in the melting range of the polymer of the build material composition. As such, the temperature selected will depend upon the polymeric build material 16 that is used. As examples, the pre-heating temperature may be from about 5° C. to about 50° C. below the melting point or the lowest temperature in the melting range. In an example, the pre-heating temperature ranges from about 50° C. to about 125° C. In another example, the pre-heating temperature ranges from about 80° C. to about 110° C. In still another example, the pre-heating temperature ranges from about 70° C. to about 105° C.

Pre-heating the layer 26A of the polymeric build material 16 may be accomplished by using any suitable heat source that exposes all of the polymeric build material 16 in the layer 26A to the heat. Examples of the heat source include a thermal heat source (e.g., a heater (not shown) integrated into the build area platform 30 (which may include sidewalls)) or the radiation source.

After the layer 26A is formed, and in some instances is pre-heated, the fusing agent 18 is selectively applied on portion(s) 28 of the polymeric build material 16 in the layer 26A. The selective application of the fusing agent 18 may be accomplished with the applicator 22A. The applicator 22A may be, for instance, a thermal inkjet printhead, a piezoelectric printhead, a continuous inkjet printhead, etc., and may extend a width of the build area platform 30.

The applicator 22A may be scanned across the build area platform 30 in the directions indicated by the arrow 40 e.g., along the y-axis. While a single applicator 22A is shown in FIG. 2 (at A), it is to be understood that the applicator 22A may include multiple applicators that span the width of the build area platform 30. Additionally, the applicators 22A may be positioned in multiple printbars. The applicator 22A may also be scanned along the x-axis, for instance, in configurations in which the applicator 22A does not span the width of the build area platform 30. This enables the applicator 22A to deposit the fusing agent 18 over a large area of the polymeric build material 16. The applicator 22A may thus be attached to a moving XY stage or a translational carriage (neither of which is shown) that moves the applicator(s) 22A adjacent to the build area platform 30 in order to deposit the fusing agent 18 in predetermined areas of the build material layer(s) 26A, 26B, etc. that has/have been formed on the build area platform 30 in accordance with the method 100 disclosed herein. The applicator(s) 22A may include a plurality of nozzles (not shown) through which the fusing agent 18 is to be ejected.

The applicator 22A may deliver drops of the fusing agent 18 at a resolution ranging from about 300 dots per inch (DPI) to about 1200 DPI. In other examples, the applicator(s) 22A may deliver drops at a higher or lower resolution. The drop velocity may range from about 10 m/s to about 24 m/s and the firing frequency may range from about 1 kHz to about 48 kHz. In one example, the volume of each drop may be on the order of about 3 picoliters (pL) to about 18 pL, although it is contemplated that a higher or lower drop volume may be used. In some examples, the applicator 22A is/are able to deliver variable drop volumes of the fusing agent 18. One example of a suitable printhead has 600 DPI resolution and can deliver drop volumes ranging from about 6 pL to about 14 pL.

To form the base structure 20 shown in FIG. 2, the layer 26A of polymeric build material 16 is patterned with the fusing agent 18, i.e., the fusing agent 18 is selectively dispensed on the layer 26A according to a pattern of a cross-section for the base structure 20. As used herein, the cross-section of the layer to be formed refers to the cross-section that is parallel to the contact surface of the build area platform 30. As an example, if the layer 34A is to be shaped like a cube or cylinder, the fusing agent 18 will be deposited in a square pattern or a circular pattern (from a top view), respectively, on at least a portion of the layer 26A of the polymeric build material 16

It is to be understood that the selective application of the fusing agent 18 may be accomplished in a single printing pass or in multiple printing passes. In an example, selective application of the fusing agent 18 is accomplished in multiple printing passes. In another example, the selectively applying of the fusing agent 18 is accomplished in a number of printing passes ranging from 2 to 4. In still another example, selectively applying of the fusing agent 18 is accomplished in 2 printing passes. In yet another example, selectively applying of the fusing agent 18 is accomplished in 4 printing passes. It may be desirable to apply the fusing agent 18 in multiple printing passes to increase the amount of the energy absorber that is applied to the polymeric build material 16, to avoid liquid splashing, to avoid displacement of the polymeric build material 16, etc.

The volume of the fusing agent 18 that is applied per unit of the polymeric build material 16 in the patterned portion 28 may be sufficient to absorb and convert enough electromagnetic radiation so that the polymeric build material 16 in the patterned portion 28 will coalesce/fuse. The volume of the fusing agent 18 that is applied per unit of the polymeric build material 16 may depend, at least in part, on the energy absorber used, the energy absorber loading in the fusing agent 18, and the polymeric build material 16 used.

After the fusing agent 18 is selectively applied in the specific portion(s) 28 of the layer 26A, the entire layer 26A of the polymeric build material 16 is exposed to electromagnetic radiation (shown as EMR Exposure between A and B in FIG. 2).

The electromagnetic radiation is emitted from a radiation source (not shown). The length of time the electromagnetic radiation is applied for, or energy exposure time, may be dependent, for example, on one or more of: characteristics of the radiation source; characteristics of the polymeric build material 16; and/or characteristics of the fusing agent 18.

It is to be understood that the exposing of the polymeric build material 16 to electromagnetic radiation may be accomplished in a single radiation event or in multiple radiation events. In an example, the exposing of the polymeric build material 16 is accomplished in multiple radiation events. In another example, the exposing of the polymeric build material 16 to electromagnetic radiation may be accomplished in a number of radiation events ranging from 3 to 8. In still another example, the exposing of the polymeric build material 16 to electromagnetic radiation may be accomplished in 3 radiation events. It may be desirable to expose the polymeric build material 16 to electromagnetic radiation in multiple radiation events to counteract a cooling effect that may be brought on by the amount of the fusing agent 18 that is applied to the build material layer 26A. Additionally, it may be desirable to expose the polymeric build material 16 to electromagnetic radiation in multiple radiation events to sufficiently elevate the temperature of the polymeric build material 16 in the portion(s) 28, without over heating the polymeric build material 16 in the non-patterned portion(s).

The fusing agent 18 enhances the absorption of the radiation, converts the absorbed radiation to thermal energy, and promotes the transfer of the thermal heat to the polymeric build material 16 in contact therewith. In an example, the fusing agent 18 sufficiently elevates the temperature of the polymeric build material 16 in the layer 26A to a temperature at or above the melting point or within or above the melting range of the polymer of the build material composition, allowing coalescing/fusing (e.g., thermal merging, melting, binding, etc.) of the polymeric build material 16 to take place. The application of the electromagnetic radiation forms the layer 34A of the base structure 20.

In some examples of the method 100, the electromagnetic radiation has a wavelength ranging from 800 nm to 4000 nm. In another example the electromagnetic radiation has a wavelength ranging from 800 nm to 1400 nm. In still another example, the electromagnetic radiation has a wavelength ranging from 800 nm to 1200 nm. Radiation having wavelengths within the provided ranges may be absorbed (e.g., 80% or more of the applied radiation is absorbed) by the fusing agent 18 and may heat the build material composition in contact therewith, and may not be substantially absorbed (e.g., 25% or less of the applied radiation is absorbed) by the non-patterned build material composition.

It is to be understood that portions of the polymeric build material 16 that do not have the fusing agent 18 applied thereto do not absorb enough radiation to coalesce/fuse. As such, these portions do not become part of the 3D object that is ultimately formed. However, the generated thermal energy may propagate into the surrounding polymeric build material 16 that does not have fusing agent 18 applied thereto. The propagation of thermal energy may be inhibited from coalescing/fusing the non-patterned build material composition in the layer 26A, for example, when a detailing or modifying agent (e.g., including a water based vehicle but no energy absorber) is applied to the polymeric build material 16 in the layer 26A that is not exposed to the fusing agent 18.

The application of additional polymeric build material 16, the selective application of the fusing agent 18, and the electromagnetic radiation exposure may be repeated a predetermined number of cycles to form the base structure 20 (shown at C in FIG. 2). The number of layers 26A, 26B, etc. included in the base structure 20 may depend upon the polymeric build material 16 that is used, the thickness of the layers 26A, 26B, etc., and the desired flexibility and bendability of the base structure. In an example, the base structure 20 may include 3 to 7 layers 34A, 34B, 34C, 34D, each having a thickness ranging from about 50 μm to about 100 μm.

Once the base structure 20 is formed, the graphene oxide membrane 12′ is applied to the base structure 20. The graphene oxide membrane 12′ may cover all or a portion of the surface of the base structure 20. In an example, the graphene oxide membrane 12′ covers at least an area where it is desirable to form the electronic component 14.

The graphene oxide membrane 12′ may be positioned using an automated machine. The automated machine may be programmed to accurately and precisely place the graphene oxide membrane 12′ into the desirable position.

It may be desirable to place the graphene oxide membrane 12′ on the base structure 20 while the base structure 20 is still tacky (from heating), but is below a temperature that could degrade the graphene oxide membrane 12′ (e.g., below 100° C., or in some instance, below 50° C.).

The graphene oxide membrane 12′ may adhere to the tacky surface of the base structure 20.

An example of the water-based ink 24 disclosed herein is then deposited on at least a portion of the graphene oxide membrane 12′. The water-based ink 24 may be applied using the applicator 22B. The applicator 22B may be the same as or similar to the applicator 22A and may be operated in a similar manner as described for the applicator 22A. Any number of printing passes may be used to form the electronic component 14, depending, in part, upon the desired conductivity and/or thickness of the electronic component 14.

The deposited water-based ink 24 is dried, leaving the solids on the surface of the graphene oxide membrane 12′. This forms the electronic component 14.

In some examples, the graphene oxide membrane 12′ and the electronic component 14 remain exposed at the surface of the base structure 20, as shown in FIG. 2 at C. This 3D printed object 42 may be incorporated into a wearable device or other flexible electronic device.

Uses for the Flexible Printed Article

Examples of the printed flexible printed article 10 (including the electronic component 14) and/or the 3D printed object (including the flexible printed article 10) may be used in a variety of devices, including wearable devices, such as activity trackers, watches, etc., or any other device in which it is desirable for the electronics to be flexible.

To further illustrate the present disclosure, examples are given herein. It is to be understood that these examples are provided for illustrative purposes and are not to be construed as limiting the scope of the present disclosure.

### EXAMPLE 1

For the example samples, a graphene oxide membrane was used as the non-conductive base substrate. For the comparative example samples, two different commercially available papers were used. One comparative paper was an untreated white office paper (Banner A4 White Office Paper, 80 GSM), and the other comparative paper was a treated paper (PEL P60, which is a surface treated paper that is commercially available from Printed Electronics Limited).

A water-based graphene ink was used. To form the example samples, the water-based graphene ink was directly inkjet printed on the graphene oxide membrane to form conductive graphene lines (e.g., tracks or traces), whose sheet resistance strongly changes with strain. The printed ink was allowed to dry.

To form the comparative example samples, the water-based graphene ink was directly inkjet printed on the white office paper or on the treated paper to form conductive graphene lines (e.g., tracks or traces). The printed ink was allowed to dry.

The number of printing passes was varied from 10 to 70 for the example samples and from 10 to 100 for the different comparative example samples.

The sheet resistance values of the conductive graphene lines on the graphene oxide membrane, on the white office paper, and on the treated paper were measured using two point probe measurements facilitated by contact pads. The results for the example samples (conductive graphene lines on the graphene oxide membrane), the first comparative example (conductive graphene lines on the commercial white office paper), and the second comparative example (conductive graphene lines on the treated paper) are shown in FIG. 3. As depicted, the sheet resistance values for the example samples are comparable to, and even better than, both types of the comparative example samples. These results indicate that, from a printing perspective, the graphene oxide membranes are equivalent to both white office paper and treated paper.

### EXAMPLE 2

Three example printed articles and three comparative example printed articles were prepared. For the example printed articles, graphene oxide membranes were used as the non-conductive base substrate. For the comparative example samples, an untreated laser printer paper was used as the substrate.

The water-based graphene ink from Example 1 was printed, using 60 printing passes) on each of the example substrates and the comparative example substrates to form a conductive graphene line having a length of about 1.8 cm. The printed ink was allowed to dry.

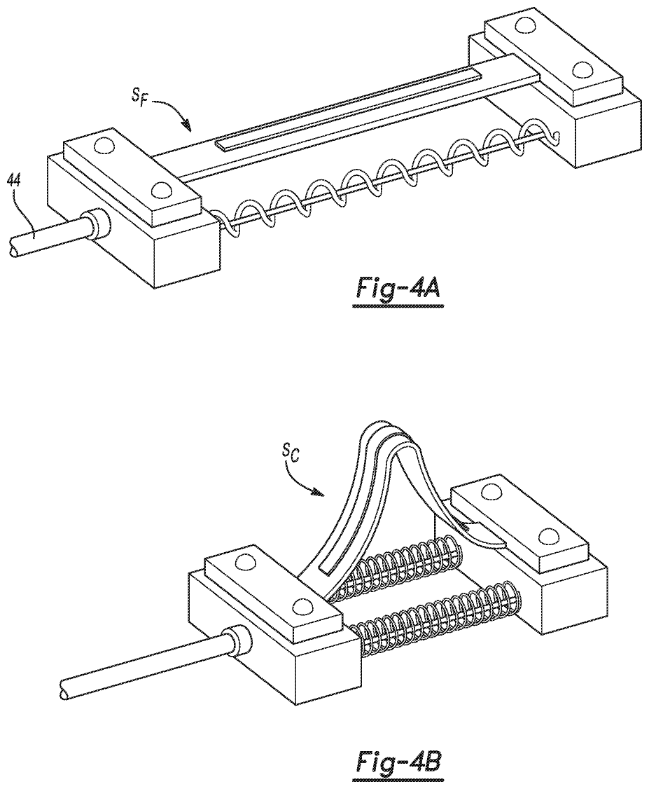

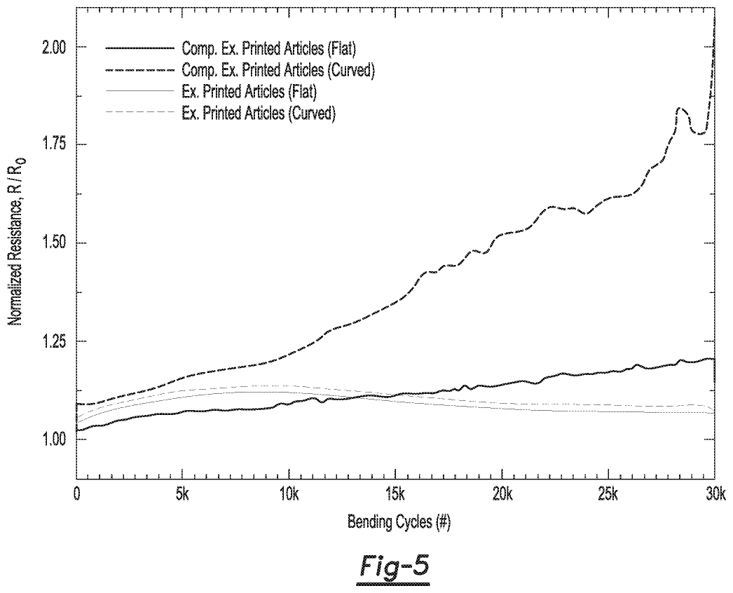

Each example printed article and each comparative example printed article was attached, at opposed ends, to a bending apparatus (shown in FIGS. 4A and 4B in different states). Using the bending apparatus (and in particular the piston 44), the printed articles were switched between a flat state S_{F} (see FIG. 4A) and a curved state S_{C} (see FIG. 4B). The bending radius during the test was about 3 mm. The resistance value of the conductive graphene lines was monitored at each state over 30,000 bending cycles. The averaged results in the flat state and in the bent or curved state for the three example printed articles and for the three comparative example printed articles are shown in FIG. 5. As shown in the graph, strong changes in resistance were observed with increasing bending cycles for the comparative example printed articles. In particular, initial resistance changes for the comparative example printed articles were observed after 5,000 cycles, and they strongly increased after 10,000 cycles. Substantially no change (e.g., ±10% of the initial value) in resistance was observed for the example printed articles over at least 30,000 cycles. The example printed articles also exhibited excellent resistance to permanent deformations.

### EXAMPLE 3

An example strain sensor was prepared by printing the water-based graphene ink from Example 1 on a graphene oxide membrane. The example strain sensor was glued (with LUVITEC K30 adhesive from BASF) to a cardboard box across the intersection of the lid and the side in order to detect the opening/closing of the lid based on changes in resistance with changes in strain as the box was opened and closed.

A comparative example strain sensor was prepared by printing the water-based graphene ink from Example 1 directly onto a second cardboard box (of the same type as used in the example strain sensor) across the same intersection.

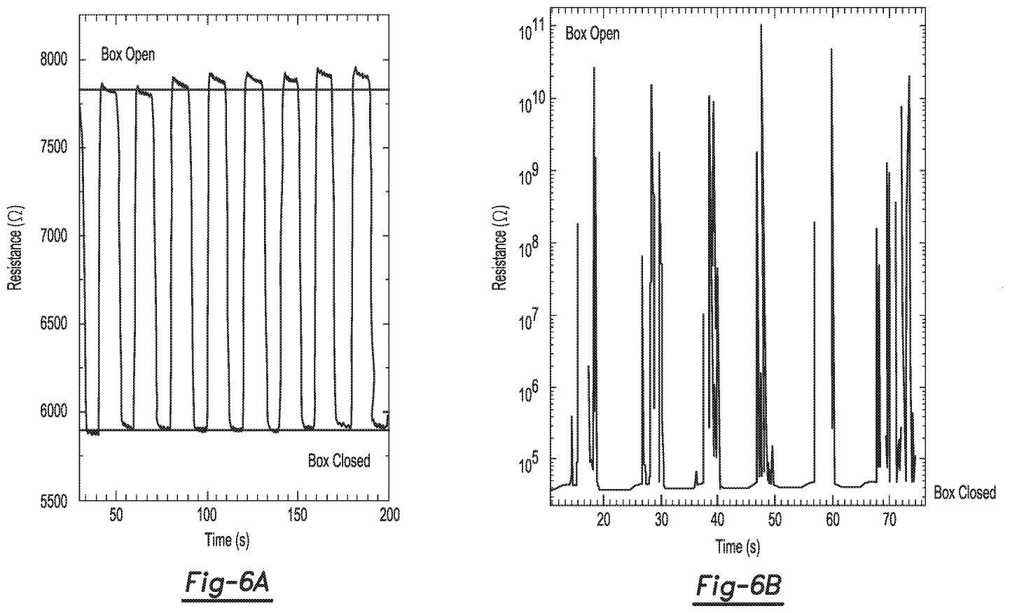

The cardboard boxes were opened and closed multiple times over a period of 200 seconds. The resistance of the example strain sensor and the comparative example strain sensor was measured consistently as the cardboard boxes were opened and closed. The results for the example strain sensor are shown in FIG. 6A and the results for the comparative example strain sensor are shown in FIG. 6B. The example strain sensor allowed for smooth and reliable measurements, which were clearly associated with the open and closed states. In contrast, the comparative example strain sensor showed several spikes, which increased as the time approached 70 seconds. The inconsistent measurements may be associated to the breakage of the cellulose fibers of the cardboard box, which can disrupt the strain sensor printed thereon.

It is to be understood that the ranges provided herein include the stated range and any value or sub-range within the stated range, as if such values or sub-ranges were explicitly recited. For example, from about 0.1 wt % active to about 50 wt % active should be interpreted to include not only the explicitly recited limits of from about 0.1 wt % active to about 50 wt % active, but also to include individual values, such as about 0.65 wt %, about 7 wt %, about 25 wt %, about 42 wt %, etc., and sub-ranges, such as from about 0.55 wt % to about 0.725 wt %, from about 1 wt % to about 20 wt %, from about 0.675 wt % to about 1.1 wt %, etc. Furthermore, when “about” is utilized to describe a value, this is meant to encompass minor variations (up to +/−10%) from the stated value.

Reference throughout the specification to “one example”, “another example”, “an example”, and so forth, means that a particular element (e.g., feature, structure, and/or characteristic) described in connection with the example is included in at least one example described herein, and may or may not be present in other examples. In addition, it is to be understood that the described elements for any example may be combined in any suitable manner in the various examples unless the context clearly dictates otherwise.

In describing and claiming the examples disclosed herein, the singular forms “a”, “an”, and “the” include plural referents unless the context clearly dictates otherwise.

While several examples have been described in detail, it is to be understood that the disclosed examples may be modified. Therefore, the foregoing description is to be considered non-limiting.

What is claimed is:

1. A flexible printed article, comprising:
a non-conductive, graphene oxide membrane base substrate; and
an electronic component positioned on the non-conductive, graphene oxide membrane base substrate.

2. The flexible printed article as defined in claim 1 wherein the electronic component includes solids of a conductive ink.

3. The flexible printed article as defined in claim 2 wherein the conductive ink is a water-based ink, and wherein the solids include conductive nanomaterials.

4. The flexible printed article as defined in claim 3 wherein the conductive nanomaterials are selected from the group consisting of graphene materials, carbon nanomaterials, metal nanomaterials, metallic transition metal chalcogenide nanomaterials, conductive polymers, and combinations thereof.

5. The flexible printed article as defined in claim 1, further comprising a plurality of the electronic components positioned on the non-conductive, graphene oxide membrane base substrate.

6. The flexible printed article as defined in claim 1 wherein the non-conductive, graphene oxide membrane base substrate has a thickness ranging from about 1 μm to about 100 μm.

7. The flexible printed article as defined in claim 1 wherein:
the electronic component includes graphene nanosheets; and
a normalized resistance of the electronic component remains within 10% of an initial normalized resistance over 30,000 bending cycles.

8. The flexible printed article as defined in claim 1 wherein the electronic component is a strain gauge.

9. A wearable device comprising the flexible printed article of claim 1.

10. A printing method, comprising:
inkjet printing a water-based ink directly on a non-conductive graphene oxide membrane base substrate to form a flexible printed article.

11. The printing method as defined in claim 10 wherein the water-based ink is a conductive ink, and wherein solids of the printed conductive ink form an electronic component.

12. The printing method as defined in claim 11 wherein the electronic component is a strain gauge.

13. The printing method as defined in claim 10 wherein the water-based ink includes a white pigment.

14. A three-dimensional (3D) printing method, comprising:
forming a base structure by iteratively:
applying layers of a polymeric build material;
patterning at least a portion of each layer with a fusing agent; and
exposing each layer to electromagnetic radiation, thereby coalescing the at least the portion of each layer;
applying a graphene oxide membrane on the base structure; and
depositing a water-based, conductive ink on at least a portion of the graphene oxide membrane, thereby forming a printed electronic component.

15. The 3D printing method as defined in claim 14 wherein:
the polymeric build material is selected from the group consisting of polyamide, a thermoplastic elastomer, and combinations thereof; and
the conductive ink is a water-based ink including conductive nanomaterials selected from the group consisting of graphene materials, carbon nanomaterials, metal nanomaterials, metallic transition metal chalcogenide nanomaterials, conductive polymers, and combinations thereof.
